(19) United States
(12) Patent Application Publication
(10) Pub. No.: US 2007/0173056 A1
(43) Pub. Date: Jul. 26, 2007

(54) Semiconductor device fabrication method and polishing apparatus

(75) Inventor: Masako Kodera, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Kabushiki Kaisha Toshiba

(21) Appl. No.: 11/652,505

(22) Filed: Jan. 12, 2007

(30) Foreign Application Priority Data
Jan. 23, 2006 (JP) 2006-013563

(51) Int. Cl. H01L 21/4763

(52) U.S. Cl. 438/633; 438/687

(57) ABSTRACT

A method for fabricating a semiconductor device includes forming a barrier metal film on a substrate with an opening defined therein, forming a copper-containing film on said barrier metal film after having formed said barrier metal film on a surface of said substrate and an inner wall of said opening, and polishing said copper-containing film and said barrier metal film while applying a voltage to said substrate in a state that said copper-containing film and said barrier metal film are exposed.

### CROSS-REFERENCE TO RELATED APPLICATION

This application is based upon and claims the benefit of priority from Japanese Patent Application No. 2006-013563, filed on Jan. 23, 2006, the entire contents of which are incorporated herein by reference.

### BACKGROUND OF THE INVENTION

1. Field of the Invention

The present invention relates to a semiconductor device fabrication method and a polishing apparatus. More particularly but not exclusively, this invention relates to a semiconductor device fabrication method for forming damascene wiring lines by polishing a barrier metal film and a copper (Cu) film, for example, and a chemical-mechanical polishing (CMP) apparatus for applying CMP to a semiconductor substrate.

2. Related Art

In recent years, the quest for higher integration and performance in semiconductor integrated circuit (LSI) devices brings development of new microfabrication technologies. Especially, in order to achieve enhanced speed performance of LSI, an attempt is made to change metal wiring material from traditional aluminum (Al) alloys to copper (Cu) or Cu alloys (i.e., copper-containing material) of low electrical resistance (these will be collectively referred to as “Cu” hereinafter). As Cu is difficult in microfabrication by dry etching techniques which have been frequently used in the formation of Al alloy wires, the so-called “damascene” method is mainly employed, which has the steps of depositing a Cu film on a dielectric film with grooves defined therein and then applying thereto chemical-mechanical polishing (CMP) to remove extra portions of the Cu film other than its groove-buried parts to thereby form a pattern of buried wires. A general approach to forming the Cu film is to form a thin seed layer by sputtering and thereafter form by electrolytic plating methods a multilayer film having a thickness of about several hundred of nm. Alternatively, in the case of forming a multilayered Cu wiring pattern, another wire-forming method is usable, which fabricates wires of the type having the so called “dual damascene” structure. In this method, deposit a dielectric film on an underlayer wire. Then, define therein openings, known as via holes, and wiring grooves for the upper-layer wire use, called the trenches. Thereafter, bury a wiring material, such as Cu, to fill both the via holes and the trenches at a time. Next, remove by CMP unnecessary surface portions of the buried Cu for planarization, thereby forming the intended buried wires.

Recently, consideration is given to use as an interlayer dielectric film an insulative material with low dielectric constant, k, which is called the “low-k” film. More specifically, the industry faces challenges for further reduction of the parasitic capacitance between adjacent interconnect wires by replacing traditional silicon dioxide (SiO₂) films having a relative dielectric constant k of about 3.9 by a low-k film with its relative dielectric constant of 3.0 or less, by way of example.

Additionally, in order to preclude Cu diffusion into a low-k film, it is a usual approach to form a barrier metal film made of tantalum (Ta) between a Cu film and low-k film. This barrier metal film also is applied CMP planarization by removal of its unnecessary portions.

In the way above, damascene Cu wiring lines for use in LSIs are formed by CMP method. However, in the case of polishing a surface at which a Cu film and a barrier metal film are simultaneously exposed by CMP, a local battery is formed due to the contact of different kinds of metals. As a result of it, galvanic corrosion takes place. Generally a slurry (i.e., polishing liquid) for use in CMP polishing is such that a plurality of chemical liquids are mixed together and is designed so that Cu becomes a cathode whereas the barrier metal becomes an anode. A reason for this is that if Cu becomes the anode then the entirety of Cu is dissolved resulting in disappearance of electrical interconnect wires. In this case, if active anode reaction (such as oxidation) occurs at the barrier metal surface, electrical charge carriers are sufficiently supplied to the Cu which acts as the cathode, so corrosion becomes hardly occurrable. Additionally, in order to suppress the corrosion of Cu wires, a technique for supplying a chemical liquid with hydrogen (H₂) or the like being dissolved in the slurry is disclosed in technical bulletins (for example, see JP-A-2003-338464).

Note here that in the case of an ordinarily used barrier metal using Ta-based material, Ta is extremely stable and slow in progress of oxidation so that any sufficient amount of electrical charge is no longer supplied from Ta which becomes the anode to Cu that becomes the cathode. As a result, not Ta but an interface portion of Cu wire adjacent to Ta becomes an alternative or substitute anode and such portion is dissolved, thereby posing a risk as to unwanted occurrence of slit-shaped corrosion. This slit-like corrosion at the Cu/Ta interface is undesirable because it impairs the reliability of wires and deteriorates electrical characteristics of devices.

### BRIEF SUMMARY OF THE INVENTION

In accordance with one aspect of this invention, a method for fabricating a semiconductor device is provided, which includes forming a barrier metal film on a substrate with an opening defined therein, forming a copper-containing film on said barrier metal film after having formed said barrier metal film on a surface of said substrate and an inner wall of said opening, and polishing said copper-containing film and said barrier metal film while applying a voltage to said substrate in a state that said copper-containing film and said barrier metal film are exposed.

In accordance with another aspect of the invention, a method for fabricating a semiconductor device includes measuring a potential of a hybrid system of a copper-containing film and a barrier metal film when a slurry is supplied to a substrate with said copper-containing film and said barrier metal film being exposed at a surface of said substrate, and based on a result of said measuring, using said slurry to polish said copper-containing film and said barrier metal film while applying a voltage to said substrate.

In accordance with a further aspect of the invention, a polishing apparatus includes a polishing unit operative to polish a substrate surface by use of a chemical liquid, and a potential measurement unit configured to measure a potential of said substrate surface with said chemical liquid being as an electrolytic material.

### BRIEF DESCRIPTION OF THE DRAWINGS

FIG. 1 is a flow chart which represents main parts of a fabrication method of a semiconductor device in an embodiment 1.

FIGS. 2A to 2C are process cross-sectional diagrams representing processes to be implemented in a way corresponding to the flow chart of FIG. 1.

FIGS. 3A to 3C are process cross-section diagrams representing processes to be implemented in a way corresponding to the flow chart of FIG. 1.

FIGS. 4A to 4C are process cross-section diagrams representing processes to be implemented in a way corresponding to the flow chart of FIG. 1.

FIG. 5 is a conceptual diagram showing a cross-sectional structure of CMP apparatus.

FIG. 6 is a diagram showing polarization curves of Cu, Ta and others.

FIG. 7 is a diagram showing polarization curves of Cu and Ta or else in the case of using another slurry.

FIG. 8 is a diagram showing Cu's potential-pH diagram.

FIG. 9 is a conceptual diagram for explanation of the appearance of a case where Cu damascene wiring lines are formed without electric potential control.

FIG. 10 is a conceptual diagram for explanation of the appearance of a case where Cu damascene wires are formed by CMP processing while at the same time performing potential control in the embodiment 1.

FIG. 11 is a diagram showing a surface SEM photograph in case Cu damascene wires are formed with the lack of the potential control.

FIG. 12 is a diagram showing a surface SEM photograph in case Cu damascene wires are formed by CMP processing while performing the potential control in the embodiment 1.

### DETAILED DESCRIPTION OF THE INVENTION

### Embodiment 1

In an embodiment 1, a case of forming Cu damascene wiring lines at a dielectric layer of low-k film will be described using the accompanying drawings below.

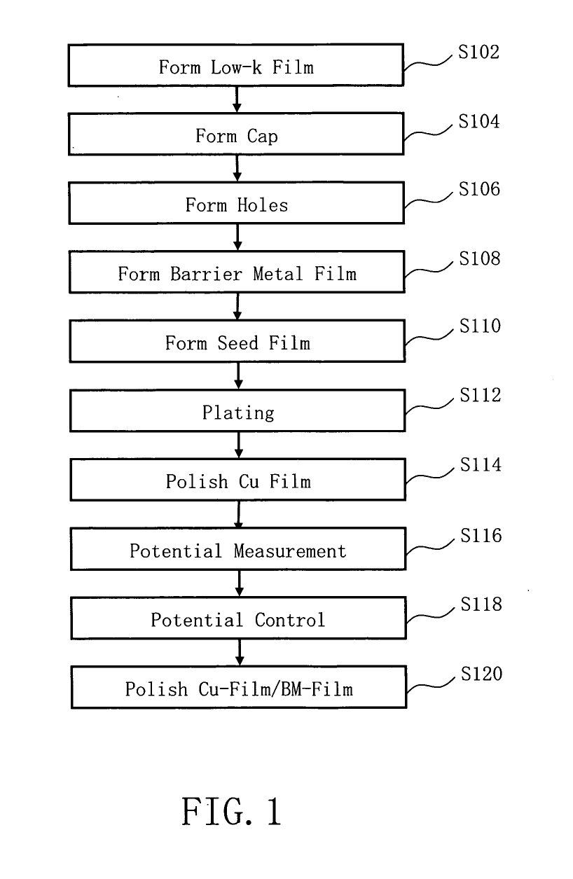

FIG. 1 is a flow chart which represents main parts of a fabrication method of a semiconductor device in the embodiment 1.

In FIG. 1, this embodiment is arranged to implement a series of process steps including a low-k film forming step S102 which forms a thin film made of a dielectric material with low relative dielectric constant k or “low-k” material, a cap film forming step S104 for forming a cap film, an opening forming step S106 for forming more than one opening or hole, a barrier metal film forming step S108 as a conductive material film forming step which forms a conductive material film using a conductive material, a seed film forming step S110, a metal plating step S112, a Cu film polishing step S114, a voltage potential measuring step 116, a potential control step S118, and a Cu-film/barrier-metal (BM) film polishing step S120.

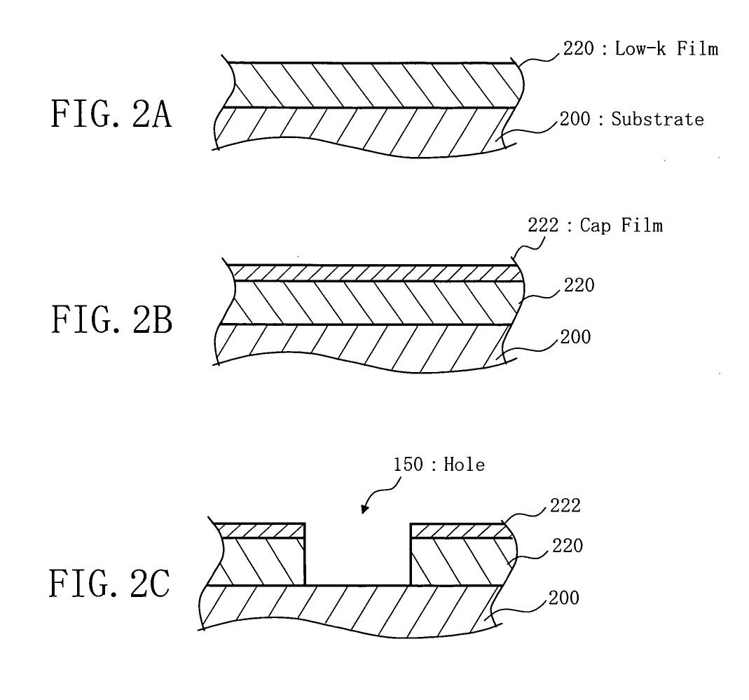

FIGS. 2A to 2C are process cross-sectional diagrams representing processes to be implemented in a way corresponding to the flow chart of FIG. 1.

In FIGS. 2A-2C, there are shown some steps of from the low-k film forming step S102 to the opening forming step S106 of FIG. 1. The following steps will be described later.

In FIG. 2A, at the low-k film forming step, a thin film of a low-k film 220 using a porous low-dielectric-constant insulative material is formed on a substrate 200 to a thickness of 200 nm, for example. Forming the low-k film 220 makes it possible to obtain an interlayer dielectric film having its relative dielectric constant k of 3.0 or less. Here, as one example, the low-k film 220 is formed by use of low-k dielectric (LKD) material (manufactured by JSR Corporation) which uses polymethylsiloxane with its relative dielectric constant of less than 2.5. Other examples of the material of low-k film 220 in addition to polymethylsiloxane include, but not limited to, a film having the siloxane backbone such as polysiloxane, hydrogen silses-quioxane and methylsilsesquioxane, a film containing as its main component an organic resin such as polyarylene ether, polybenzoxazole or polybenzocyclobutene, and a porous film such as a porous silica film. Using any one of these LKD materials makes it possible for the low-k film 220 to have the relative dielectric constant of less than 2.5. An exemplary approach to forming such film is to use the so-called spin-on-dielectric (SOD) coating method which forms a thin film through spin coating of liquid solution and thermal processing applied thereto. For instance, the film fabrication is achievable in a way such that a wafer with a film being formed thereon by a spinner is baked on a hot plate in a nitrogen-containing atmosphere and is finally subjected to curing on the hot plate at a temperature higher than the baking temperature. By appropriately choosing the low-k material and properly adjusting film forming process conditions, it is possible to obtain the aimed porous dielectric film having a prespecified physicality value(s). Additionally, an example of the substrate 200 is a silicon wafer having its diameter of 300 millimeters. Note here that an explanation is omitted as to the formation of devices or circuit elements which are positioned at lower layers of the low-k film 220.

In FIG. 2B, at the cap film forming step, a layer of silicon oxycarbide (SiOC) is deposited by CVD as a cap insulator film on the low-k film 220 to a thickness of 50 nm, for example, thereby forming a thin-film of SiOC film 222. Forming the SiOC cap film 222 makes it possible to protect its underlying low-k film 220 that is difficult to be directly applied lithography, and thus enables formation of a pattern in the low-k film 220. Examples of the cap insulator film material other than SiOC are dielectric materials with a relative dielectric constant of 2.5 or greater, as selected from the group consisting of tetra-ethoxy-silane (TEOS), SiC, silicon carbohydride (SiCH), silicon carbonitride (SiCN), SiOCH, and silane (SiH₄). Although the film fabrication is done here by CVD, other similar methods are alternatively be employable.

In FIG. 2C, at the opening forming step, holes (one example of the openings) including an illustrative hole 150 that is a wiring groove structure for damascene wire fabrication are defined by lithography and dry etching techniques in the SiOC film 222 and low-k film 220. For the substrate 200 with a resist film being formed on the SiOC film 222 through resist deposition and lithography processes such as exposure (not shown), the exposed SiOC film 222 and its underlying low-k film 220 are selectively removed away by anisotropic etching techniques, thereby making it possible to form the hole 150 substantially vertically with respect to the surface of substrate 200. For example, as one example, the hole 150 may be formed by a reactive ion etching (RIE) method.

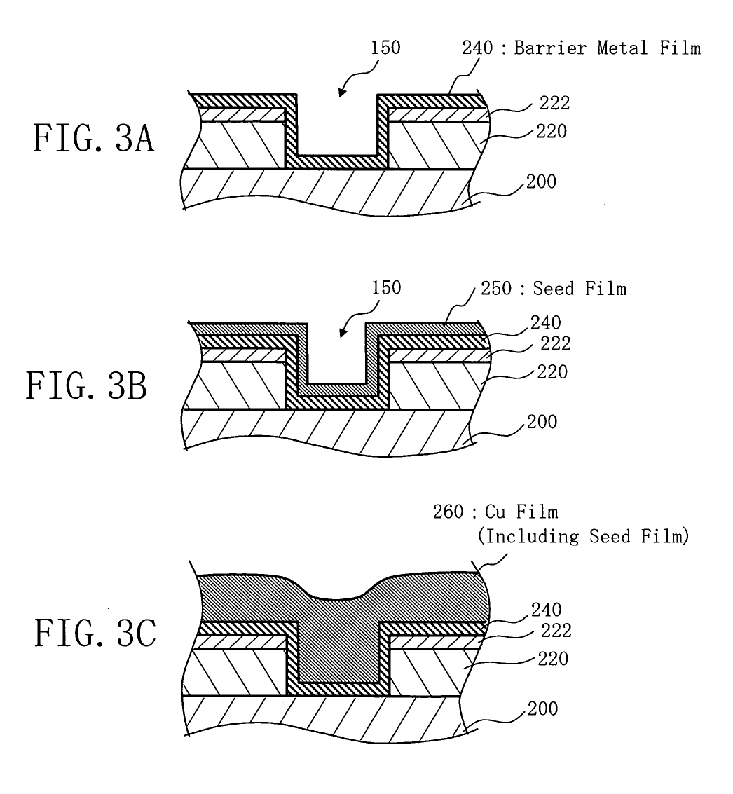

FIGS. 3A to 3C are process cross-section diagrams representing processes to be implemented in a way corresponding to the flow chart of FIG. 1.

In FIGS. 3A-3C, there are shown the steps of from the barrier metal film forming step S108 to the plating step S112. The following steps will be described later.

In FIG. 3A, at the barrier metal film forming step, a barrier metal film 240 which is made of a chosen barrier metal material is formed in the hole 150 that was defined by the opening forming process and also on a surface of the SiOC film 222. Within a sputtering apparatus using a sputter technique which is one of physical vapor deposition (PVD) methods, a thin film of tantalum (Ta) is deposited to a thickness of 5 nm for example, thereby forming the barrier metal film 240. The deposition of the barrier metal material is achievable not only by PVD but also by CVD methods, such as for example atomic layer deposition (ALD) or atomic layer chemical vapor deposition (ALCVD). In the latter case, it is possible to improve the coverage ratio so that it is better than that in the case of using PVD methods. Additionally the material of the barrier metal film is not exclusively limited to Ta. This film may alternatively be made of a tantalum-based tantalum-containing material such as tantalum nitride (TaN), a titanium-based titanium-containing material such as titanium (Ti), titanium nitride (TiN) or else or may be a multilayer film made of more than two of these materials in combination, such as Ta and TaN or the like. Further examples usable herein are a ruthenium-based ruthenium-containing material such as ruthenium (Ru), a tungsten-based tungsten-containing material such as tungsten (W), or metallic materials which are lower in corrosion potential than Cu that becomes wiring material.

In FIG. 3B, at the seed film forming step, a Cu thin-film is deposited (formed) as a seed film 250 (one example of the copper-containing film) by PVD, such as sputtering or else, on the inner wall of the hole 150 with the barrier metal film 240 formed thereon and also on the surface of substrate 200. This thin film will become a cathode pole for use in the next-executed electrolytic plating process. Here, the seed film 250 is formed to have a thickness of 50 nm, for example.

In FIG. 3C, at the plating step which becomes one example of the copper-containing film forming process, an electrochemical growth method such as electrolytic plating or else is used to deposit, with the seed film 250 being as the cathode pole, a thin film of Cu film 260 (one example of the copper-containing film) in the hole 150 and on the surface of substrate 200. Here, the Cu film 260 is deposited to a thickness of 800 nm. After having deposited it, perform annealing treatment at a temperature of 250° C. for 30 minutes, for example.

Then, extra Cu film 260 and barrier metal film 240 which are deposited on the hole 150 are removed from such the state to thereby form a pattern of damascene wiring lines.

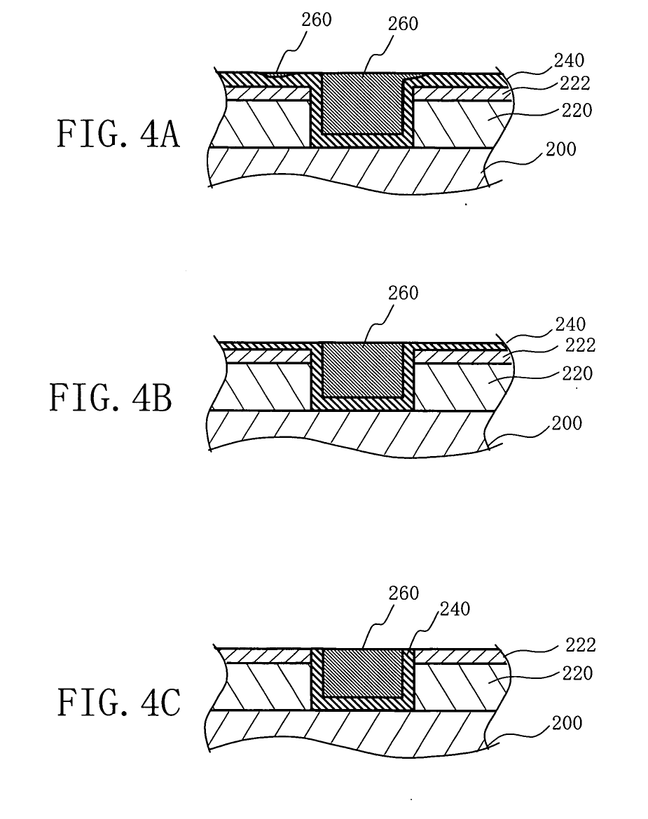

FIGS. 4A to 4C are process cross-section diagrams representing processes to be implemented in a way corresponding to the flow chart of FIG. 1.

In FIGS. 4A-4C, there are shown the steps of from the Cu film polishing step S114 to the Cu-film/BM-film polishing step S120.

In FIG. 4A, at the Cu film polishing step which becomes a first CMP step, CMP method is used to polish the surface of the substrate 200 for removal of the Cu film 260 which contains the seed film 250 that becomes a wiring layer as a conductive part deposited at the surface of the barrier metal film 240 except the holes.

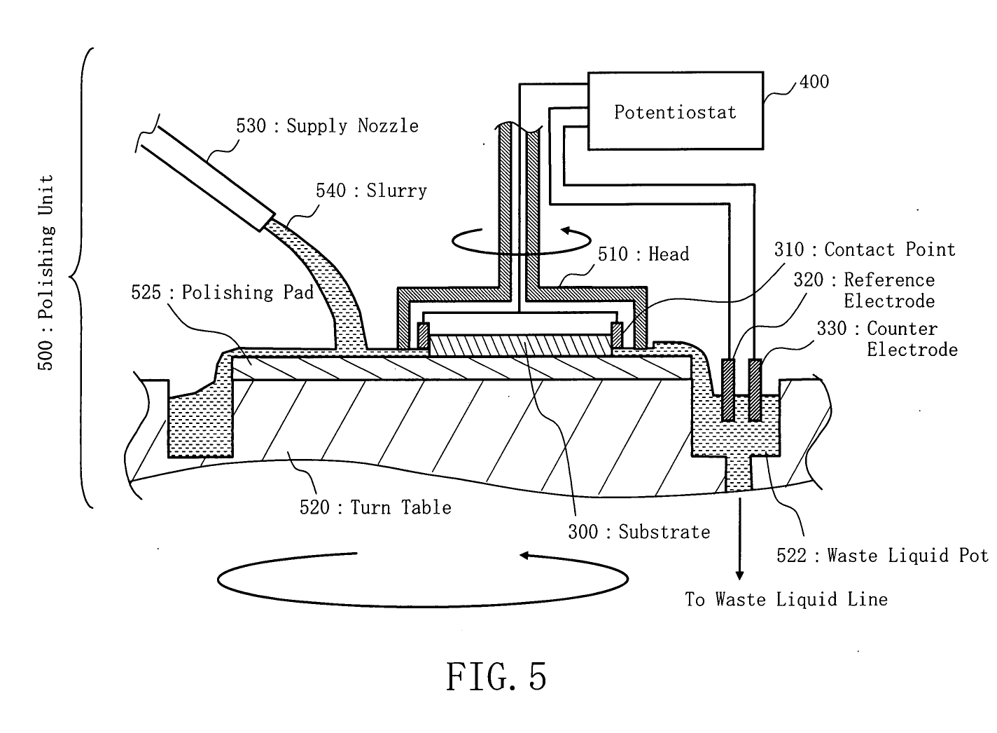

FIG. 5 is a conceptual diagram showing a cross-sectional structure of CMP apparatus.

The CMP apparatus has a head 510 which becomes one example of a polishing unit 500, a turn table 520, a polishing pad 525, a supply nozzle 630 and others. The CMP apparatus also has a potentiostat 400 (one example of the potential measuring unit, current density measuring unit) with a contact point 310, a reference electrode 320, and an counter electrode 330 being connected thereto. While the turn table 520 to which the polishing pad 525 is applied or pasted is driven to rotate at 50 to 120 min⁻¹ (rpm), a substrate 300 is attached by the head 510 that supports the substrate 300 to the polishing pad 525 with the application of a polish load P of 100 to 300 hPa. A rotation number of the head 510 is set at 50 to 120 min⁻¹ (rpm). A flow of slurry (polishing liquid) 540 (one example of the chemical liquid) is supplied onto the polishing pad 525 from the supply nozzle 530 at a flow rate of 0.1 to 0.2 L/min (100 to 200 ml/min).

Firstly, polishing is performed up to a state that the Cu film 260 and the barrier metal film 240 are exposed as shown in FIG. 4A.

Then, at the potential measuring step, for the substrate 200 with the Cu film 260 and the barrier metal film 240 being exposed at its surface, an attempt is made to measure a voltage potential of a hybrid system of the Cu film 260 and barrier metal film 240.

In FIG. 5, the measurement of the potential of the hybrid system of the Cu film 260 and barrier metal film 240 is carried out in such a way that an external power supply and the substrate 300 are conducted together to cause the external power supply to be connected to a standard electrode and the counter electrode so that the substrate 300 and the reference electrode 320 that becomes the standard electrode plus the counter electrode 330 are conducted together with the slurry 540 being as an electrolytic material. In other words, as shown in FIG. 5, an apparatus configuration which is the same as the potentiostat 400 with the surface of substrate 300 being as a working electrode may be added to the CMP apparatus. As a practical method of causing the external power supply and the substrate 300 to be conducted together, the contact point 310 that is connected to the potentiostat 400 is provided at a position at which it comes into contact with a peripheral portion of the substrate 300 (including a bevel portion whereat the Cu film 260 or the barrier metal film 240 remains at the surface) through the head 510 of CMP apparatus which supports the substrate 300. Usually the Cu film 260 is formed up to the side face of substrate 300; therefore, in FIG. 5, the contact point is provided at the substrate side face. Then, let it be conducted to the side face of substrate 300 by way of the contact point 310 from the potentiostat 400. On the other hand, the reference electrode 320 and counter electrode 330 that are connected to the potentiostat 400 are provided at locations nearest to the substrate 300 to enable them to be dipped into the slurry 540. Here, an example is shown which is arranged so that a groove-shaped waste liquid pot 522 which becomes a slurry reservoir is provided at an outer edge of the turn table 520 to cause the reference electrode 320 and counter electrode 330 to be dipped at such portion to ensure that the reference electrode 320 and the counter electrode 330 are dipped into the slurry 540 without fail. For instance, in such the state, potential measurement is done while at the same time causing the potentiostat 400 to perform adjustment in such a way as to prevent current flow between the counter electrode 330 and the substrate 300, thereby making it possible to measure the corrosion potential of the hybrid system of the Cu film 260 and barrier metal film 240. In the way stated above, by use of the three-electrode type potentiostat 400 with the working electrode and the reference electrode 320 plus the counter electrode 330, it is possible to achieve the intended measurement even where the resistance is small and the current is less.

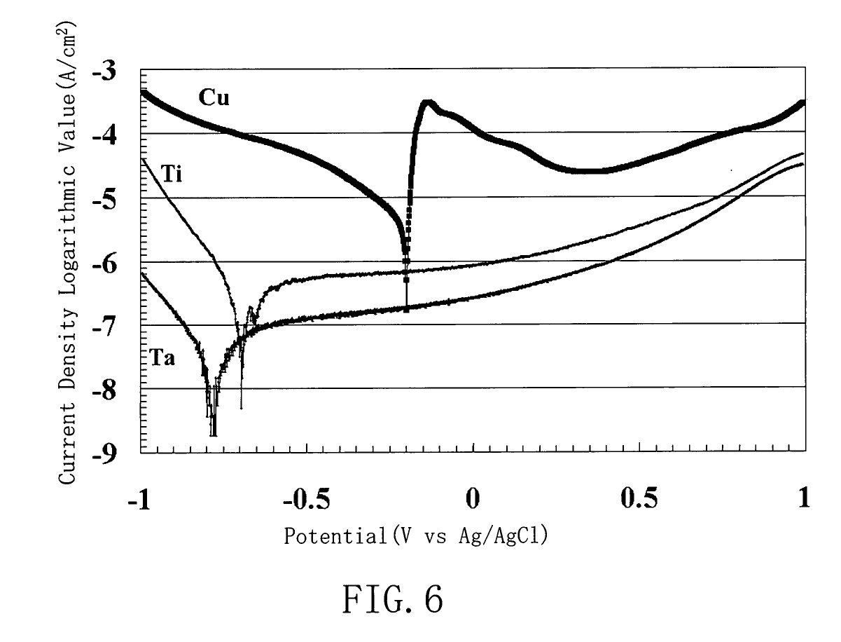

FIG. 6 is a diagram showing polarization curves of Cu and Ta or like material.

As previously stated, generally, the slurry that is used for CMP polishing is designed so that Cu becomes the cathode whereas the barrier metal is the anode. This is because of the fact that if Cu becomes the anode then Cu is entirely dissolved, resulting in disappearance of wires. In this case, if active anode reaction (such as oxidation) occurs at the barrier metal surface, then a sufficient amount of electrical charge is supplied to Cu that is the cathode whereby the corrosion hardly takes place. However, in the case of Ta-based barrier metals which are usually used, Ta is extremely stable and slow in progress of oxidation so that any sufficient amount of charge is no longer supplied from Ta to Cu. Alternatively a Cu wire portion adjacent to Ta becomes a substitute anode. Such portion is dissolved and thus becomes corrosion. Describing in greater detail here, although both an anode current and a cathode current are flowing even at the anode, it merely acts as the anode because the anode current is greater than the other. Similarly at the cathode also, although both a cathode current and an anode current are flowing, it serves as the cathode since the cathode current is larger than the other. Although it is impossible to obtain respective absolute values of the anode current and the cathode current through measurement, it is possible to measure a difference between the anode current and the cathode current. In the rest of the description, in case the difference between the anode current and the cathode current is a positive value, this will simply be called the anode current; if it is a negative value then its absolute value will simply be called the cathode current.

In addition, wiring leads for use in LSIs are made of at least two kinds of metals, i.e., a wire main material (such as Cu) and a barrier metal (such as Ta). Consequently, it is necessary to take into consideration not only the corrosion of each individual metal but also the corrosion of a hybrid system of a wire and barrier metal. In this case, what is done first is to form a polarization curve for a respective one of the wire (such as Cu) and the barrier metal (such as Ta). The polarization curve is the one that indicates a change of current density (i) occurring due to a change in voltage potential (E) of each electrode (Cu or Ta) in a logarithmic relationship (log|i|) of E and the absolute value of current density (i) as shown in FIG. 6. A cross-point of two polarization curves or its nearby portion corresponds to the corrosion potential (Ecorr) and corrosion current density (icorr) in the hybrid system.

In FIG. 6, its longitudinal axis indicates the current density's logarithmic value whereas its abscissa axis indicates the potential. And, in FIG. 6, polarization curves are shown in a case where CMS74xx (manufactured by JSR Corporation) which is a commercially available slurry is used as the slurry 540 (one example of the chemical liquid) which becomes an electrolyte. The corrosion potential of a hybrid system in which two kinds of metals, e.g., Cu and Ta, exist simultaneously as electrodes is usually positioned between a natural potential of Cu on the cathode side and a natural potential of Ta on the anode side. It is apparent from the polarization curves shown in FIG. 6 that it becomes almost adjacent to −0.2 volts versus Ag/AgCl electrode (abbreviated as “V vs. Ag/AgCl” or “VvsAg/AgCl”), which becomes a nearby location of a cross-point of two polarization curves. Since the corrosion potential of the hybrid system in which two kinds of metals, Cu and Ta, exist simultaneously as the electrodes is usually positioned between the natural potential of Cu and the natural potential of Ta as stated above, a difference in current density between Cu and Ta becomes extremely larger in cases where the potential is even slightly shifted toward the negative side. For example, the absolute value of the density of a cathode current flowing on Cu becomes undesirably about thirty times greater than the absolute value of the density of an anode current that flows on Ta. Such imbalance of the anode current and the cathode current brings occurrence of excess and deficiency of charge give-and-receive or “delivery” at a Cu/Ta interface, which leads to corrosion at the interface. Substantially the same goes with the corrosion potential of a hybrid system in which two kinds of metals of Cu and Ta coexist as electrodes.

Note here that in FIG. 6, a difference between the current density on Cu and the current density on Ta becomes less or minimal in a potential region of +0.6 to +1.0 V vs. Ag/AgCl. It is considered that this is because the anode reaction is suppressed due to the formation of a protective film of Cu complex on Cu if the potential becomes such the level so that the Cu's current density decreases. As previously stated, since the slit-shaped corrosion takes place due to the imbalance of reaction current densities on Cu and on the barrier metal, it is effective for preclusion of corrosion to perform CMP in the potential region in which the current density difference becomes minimized.

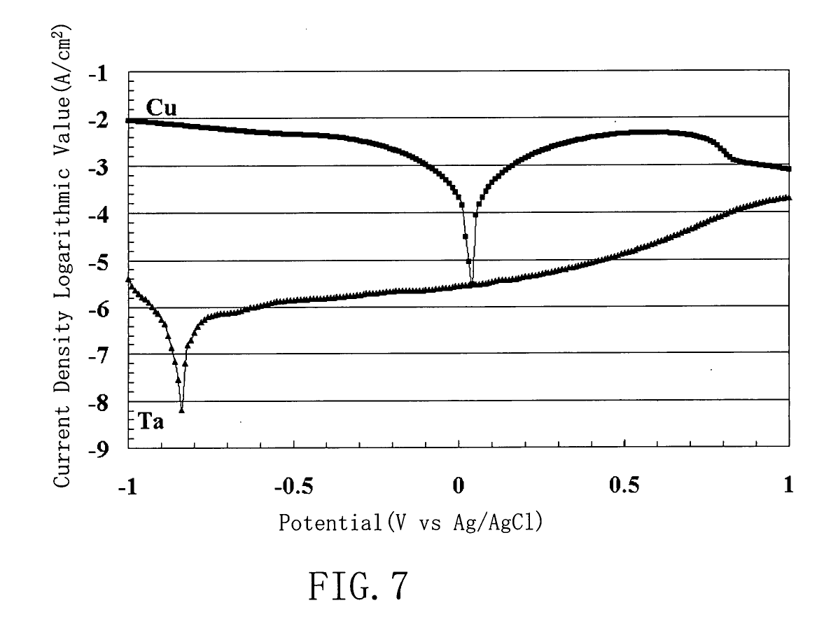

FIG. 7 is a diagram showing polarization curves of Cu and Ta or the like in a case where another slurry is used.

In FIG. 7, polarization curves are shown in case CMS83xx (manufactured by JSR Corp.) which is a commercially available slurry is used as the slurry 540 (one example of the chemical liquid) which becomes an electrolyte. As apparent from the polarization curves shown in FIG. 7, the corrosion potential of a hybrid system in which two kinds of metals, e.g., Cu and Ta, exist simultaneously as electrodes becomes approximately near 0 V vs. Ag/AgCl, which is a nearby position of a cross-point of two polarization curves. In addition, since the corrosion potential of the hybrid system is placed between the natural potential of Cu and the natural potential of Ta as stated above, it is similar in that a difference in current density between Cu and Ta becomes very large when the potential is even scantly shifted toward the negative side. And in FIG. 7, a difference between the current density on Cu and the current density on Ta becomes less or minimal in a potential region of +0.8 to +1.0 VvsAg/AgCl. As previously stated, the slit-like corrosion occurs due to the imbalance of reaction current densities on Cu and on the barrier metal, it is effective for corrosion prevention to perform CMP in the potential region in which the current density difference becomes minimized.

Although the polarization curves of two exemplary slurries are shown here, evaluation results of many other slurries have also demonstrated that the current density difference of Cu and barrier metal was less or minimized in a similar potential range. From this fact also, it can be said that it is generically effective for the corrosion prevention to perform adjustment in such a way that the potential of a hybrid system of the Cu film 260 and barrier metal film 240 falls within the potential range of +0.6 to +1.0 VvsAg/AgCl. More desirably, it is preferable to adjust so that the potential is within a potential range of from +0.8 to +1.0 VvsAg/AgCl.

Consequently, as a result of the measurement in the above-stated process as the potential control step, in case the potential of the hybrid system of the Cu film 260 and the barrier metal film 240 is less or “negative” than +0.6 to 1.0 VvsAg/AgCl, adjustment is performed by the potentiostat 400 in such a way that the potential of the hybrid becomes +0.6 to +1.0 VvsAg/AgCl. In other words, adjustment is done by applying a voltage to the substrate 300 through the contact point 310.

Then, in FIG. 4B, at the second half of the Cu film polishing process, the Cu film 260 and barrier metal film 240 which are exposed to the surface of the substrate 300 are polished while simultaneously applying a voltage to the substrate 300 until the Cu film 260 becomes absent on the surface of substrate 300 except the hole(s) 150.

By performing adjustment by the potentiostat 400 so that the potential of the hybrid system becomes +0.6 to +1.0 VvsAg/AgCl, the potential of Cu also becomes equal to or greater than +0.6 VvsAg/AgCl together with the potential of Ta, because the working electrode is a hybrid electrode of Cu and Ta. Thus, anode reactions, such as oxidation, complex formation and others, make progress on Cu also. Generally speaking, with the currently commercially available slurries for the Cu—CMP use, the natural potential of Cu is −0.2 to +0.5 VvsAg/AgCl. Accordingly, even when changing the potential of Cu to about +0.6 VvsAg/AgCl through potential manipulation by means of an external power supply, there is no large potential change when compared to a potential change of Ta and, for this reason, the risk of appearance of bad influence on Cu's CMP is extremely less. Note however that if the potential of Cu is made noble to an extent that it is greater than +1.0 VvsAg/AgCl then Cu's anode reaction can rapidly progress at this time, which leads to the risk of dissolution. In view of this, it is desirable that the Cu potential be within the range of +0.6 to +1.0 VvsAg/AgCl.

It is noted here that the electrical conduction to the substrate 300 which becomes the working electrode is not limited to the contact from the side face of substrate 300, and it is also permissible to provide the contact point 310 in such a way as to come into contact with a back surface of the substrate 300. With such the method, it is possible to cause it to be electrically conducted to the Cu film 260 and the barrier metal film 240 via a silicon wafer. Also note that when providing a contact point which is in contact with either the side face or the back face of substrate 300, there is provided no specific limitation as to the number of contact points 310. One or a plurality of contact points may be provided. Additionally there is no limitation as to the layout positions of such contact points 310. Any adequate number and layout may be chosen.

In addition, as the method for conducting it to the Cu film 260 and the barrier metal film 240, more than one contact point for contact with the Cu and the barrier metal on the surface of substrate 300 may be provided on the polishing surface of the polishing pad 525 or the like. Additionally the polishing pad 525 should not exclusively be made of a polyurethane foam which has traditionally been used. As one example, a pad that is formed of a material having electrical conductivity may be used to achieve electrical conduction to the Cu film 260 and barrier metal film 240 on the surface of substrate 300. A preferable example of such conductive pad is a carbon-made pad or else.

In addition, although in the example of FIG. 5 the groove-like slurry reservoir (chemical liquid reservoir) is provided at the outer periphery of the turn table 520 to cause the reference electrode 320 and the counter electrode 330 to be dipped at such portion to ensure that the reference electrode 320 and the counter electrode 330 are surely dipped in the slurry 540, this is not to be construed as limiting the invention. For example, it is also permissible to let the reference electrode 320 and the counter electrode 330 come into direct contact with the slurry 540 which flows on the polishing pad 525.

Additionally, although in the above-noted examples the current density difference of the Cu film 260 and the barrier metal film 240 becomes minimized in the range of +0.6 to +1.0 VvsAg/AgCl, it is also estimated that the current density difference of the Cu film and the barrier metal film becomes minimal in other potential ranges with development of various kinds of slurries in near future. In such case, an optimal potential range is selectable without adhering to the range of +0.6 to +1.0 VvsAg/AgCl. It is preferable to adjust the optimum potential range in a way such that the current density of the Cu film 260 becomes equal to or less than a value which is three times greater than the current density of the barrier metal film 240.

As described above, it is effective to perform the anode polarization which heightens the potential of the working electrode in the state that both the Cu film 260 and the barrier metal film 240 are exposed on the surface of the substrate 300 especially at the second half stage of the Cu—CMP processing. Corrosion can readily take place because of the fact that the slurry used for Cu film polishing process (Cu—CMP) that becomes the first CMP step is stronger in etching action than the slurry used for the Cu-film/BM-film polishing process (BM-CMP) which becomes the second CMP step. Thus, it becomes more effective to perform the potential control in the Cu—CMP processing. In this case, potential measurement may be carried out at a time point that the barrier metal film 240 is exposed in mid course of CMP. Such exposure of the barrier metal film 240 may be detected by an endpoint detector. It is also desirable that similar potential control is performed while electrical conduction is taken between the Cu film 260 and barrier metal film 240 on the surface of substrate 300 even during the Cu-film/BM-film polishing process (BM-CMP) that becomes the second CMP step to be later described.

Additionally, the potential of Cu or barrier metal can sometimes change due to adsorption of slurry components during CMP. Although a need for resetting the setup of a potential hardly arises since the potential adjustment range is as wide as +0.6 to +1.0 VvsAg/AgCl in ordinary cases, it is also acceptable to perform potential measurement of the hybrid system during CMP at appropriate time points if necessary and redo the potential setup at such event.

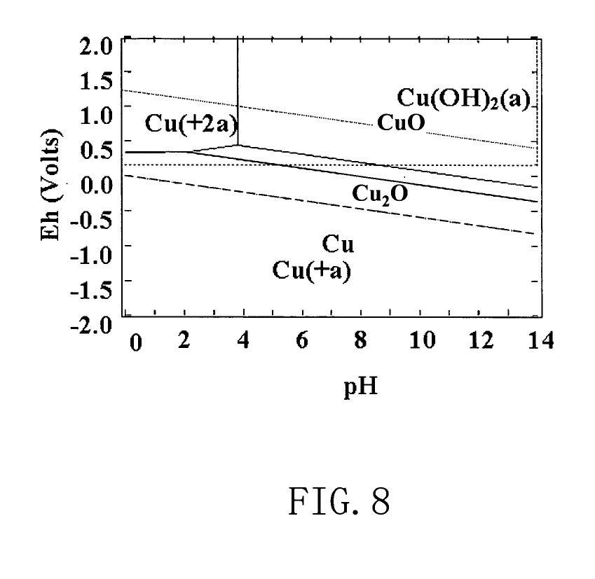

FIG. 8 is a diagram showing a potential versus pH equilibrium diagram (Pourbaix or “E-pH” diagram) of Cu.

Upon execution of anode polarization by means of the above-stated potential control, anode reaction progresses simultaneously not only on the barrier metal film 240 but also on the Cu film 260. However, if the anode reaction of Cu film 260 is anode oxidation, then there are no corrosion problems; therefore, as can be seen from FIG. 8, it is desirable to adjust as much as possible the slurry 540 to an alkali region (more than pH4) from the neutrality that Cu elution rarely occurs and the oxidation is easy to progress. The slurry of from neutrality to alkalinity is advantageous for acceleration of oxidation of the barrier metal. In such the pH region, even when the potential is shifted to be noble in order to promote the anode reaction, Cu is not dissolved, resulting in progress of the formation of an oxide film, such as Cu₂O, CuO or else. In case a chelating agent (such as organic acid) is contained in the slurry 540, Cu-organic acid complex is formed; however, if a hardly soluble complex is formed then the Cu surface is passivated in some cases. On the contrary, in the case of a slurry composition which can become the elution of Cu, the composition may be adjusted by pre-addition of a hardly soluble chelate agent, corrosion preventive compound or interface activator or detergent in such a way as to form a protective film on the Cu surface. Alternatively, the anode oxidation of the barrier metal film 240 may be done within a specific potential range in which the elution of either the hardly soluble chelate agent or Cu does not occur.

In FIG. 4C, as the Cu-film/BM-film polishing process which becomes the second CMP step, the surface of the substrate 200 is polished by CMP method to remove the barrier metal film 240 which was deposited on a surface of the SiOC film 222 other than the hole(s) and the Cu film 260 containing therein extra portions of the seed film 250 over the hole(s). Then, as shown in FIG. 4C, planarization is carried out to thereby enable the formation of damascene wires. As previously stated, also in the Cu-film/BM-film polishing process (BM-CMP) that becomes the second CMP step, it is desirable to perform the above-stated potential control while electrical conduction is taken between the Cu film 260 and barrier metal film 240 on the surface of substrate 300. Thus, an apparatus configuration therefor may be arranged in a similar way to the apparatus arrangement of FIG. 5. The kind of the slurry as used herein and the polishing rate and others may be properly selected on a case-by-case basis.

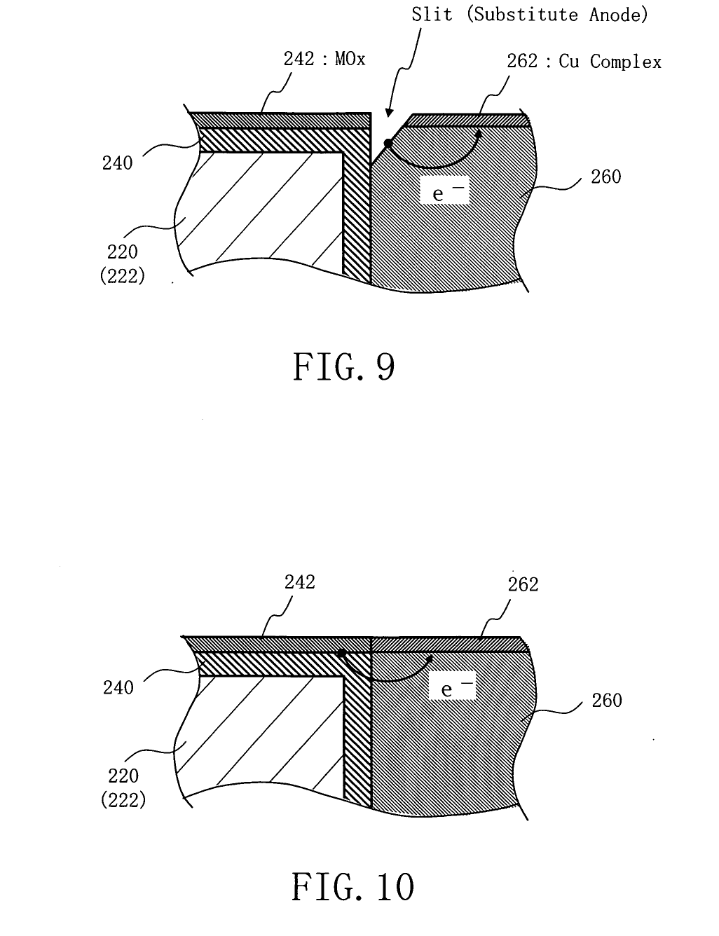

FIG. 9 is a conceptual diagram for explanation of the appearance of a case where Cu damascene wiring lines are formed with no voltage potential control.

FIG. 10 is a conceptual diagram for explanation of the appearance in a case where Cu damascene wires are formed by CMP treatment while at the same time performing the potential control in the embodiment 1.

As shown in FIG. 9, when a Cu damascene wire is formed without the potential control, the anode current on the barrier metal film 240 is less so that the anode reaction is less whereby MOₓ 242 which becomes an oxide film of the barrier metal film 240 is not formed sufficiently. For this reason, a sufficient amount of charge is not supplied to the Cu film 260, so the Cu film 260 per se becomes a substitute anode at the interface of the Cu film 260 and barrier metal film 240 and is dissolved, resulting in occurrence of corrosion. And, the charge that is supplied by the substitute anode behaves to chemically reduce or deoxidize a Cu complex 262 on the Cu film 260. In contrast, in case the Cu damascene wire is formed by CMP processing while at the same time performing the potential control in the embodiment 1, as shown in FIG. 10, the anode reaction of the barrier metal film 240 is accelerated whereas the formation of Cu complex 262 on the Cu film 260 is accelerated whereby the anode reaction of Cu film 260 is suppressed. Due to this, a difference between the cathode current on the Cu film 260 and the anode current on the barrier metal film 240 becomes smaller. More specifically, a sufficient amount of charge for chemical reduction of the Cu complex 262 is supplied from the side of the barrier metal film 240 toward the Cu film 260 side. Thus it is possible to suppress corrosion. Practical surface scanning electron microscope (SEM) photographs will be shown below.

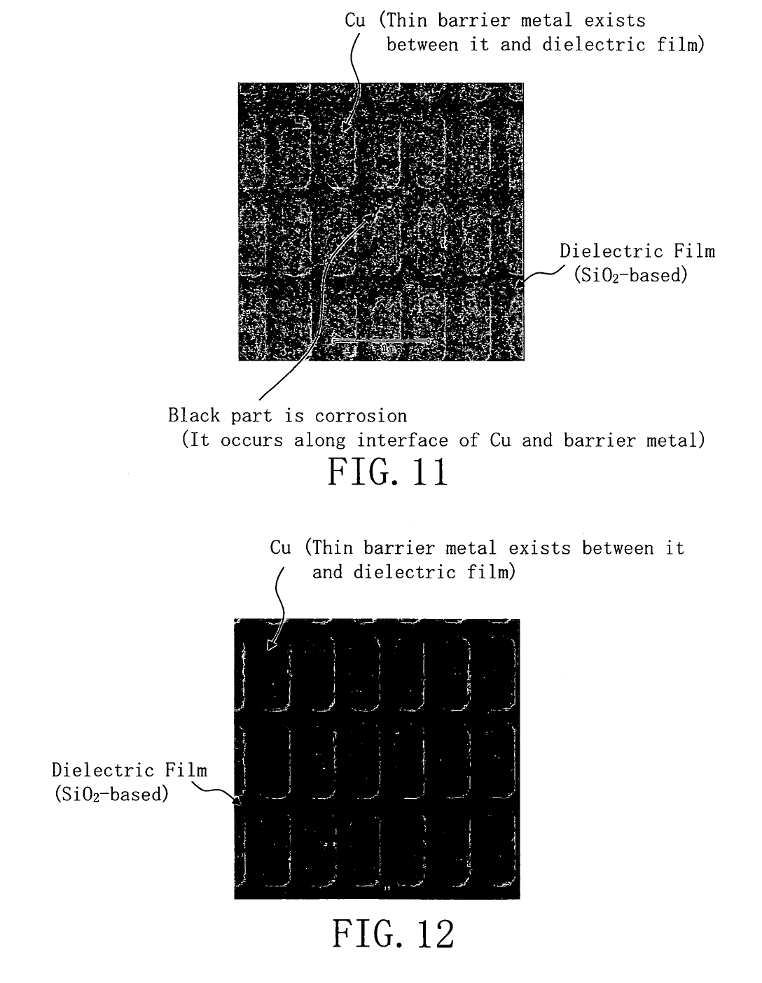

FIG. 11 is a diagram showing a surface SEM photograph in case Cu damascene wires are formed without performing the potential control.

FIG. 12 is a diagram showing a surface SEM photograph in case Cu damascene wires are formed by CMP processing while performing the potential control in the embodiment 1.

In FIGS. 11 and 12, there is shown a case where not the low-k film 220 but an SiO₂-based material is used as the dielectric film. As shown in FIG. 11, it can be seen that in case Cu damascene wires are formed without performing the potential control, corrosion takes place at an interface between Cu and a barrier metal inside of the dielectric film. On the other hand, as shown in FIG. 12, in case Cu damascene wires are formed by CMP processing while at the same time performing the potential control, it can be seen that any corrosion does not occur.

In the embodiment 1 above, the semiconductor device fabrication method which suppresses corrosion at the interface of a wire and barrier metal has been explained. Also explained is the polishing apparatus capable of suppressing such corrosion at the interface of the wire and barrier metal.

In accordance with the embodiment 1, it is possible to adjust the voltage potential of a hybrid system of a copper-containing film and a barrier metal film to the extent that a difference between the cathode current density of the copper-containing film and the anode current density of the barrier metal film becomes smaller. Thus it is possible to supply a sufficient amount of electrical charge from the barrier metal film to the copper-containing film. This makes it possible to suppress corrosion at the interface of a wire and a barrier metal.

### Embodiment 2

Although the embodiment 1 is arranged so that the contact point 310 is disposed on the side face or the back surface of the substrate 300 as shown in FIG. 5 to thereby enable execution of the potential measurement while performing CMP processing or in mid course of CMP processing, this invention should not exclusively be limited to this arrangement.

For example, a natural potential of Ta in the slurry 540 to be used is measured. The natural potential is a potential level which was measured while performing adjustment by a potentiostat to ensure that no current flows between the reference electrode and a test piece of Ta in the state that the test piece of Ta (Ta material piece) is merely dipped into the slurry 540. In case any attachments and reactive films are absent on the surface of Ta, the natural potential is identical to a corrosion potential. However, in most cases, it rarely happens that the natural potential and corrosion potential are identical to each other since some kinds of attachments or else are present on the surface of a metal film which is kept in the atmosphere. In case the next measured natural potential is less than +0.6 VvsAg/AgCl, the potential is operated from an external power supply in a way such that the potential becomes +0.6 to +1.0 VvsAg/AgCl. And, at the CMP apparatus shown in FIG. 5 also, a voltage is applied by an extent which is the same as such the potential operation. It may be arranged to perform CMP under this condition. When control is provided to cause the potential of Ta to become +0.6 to +1.0 VvsAg/AgCl, it is possible to set the potential of Cu also to +0.6 to +1.0 VvsAg/AgCl in the same way as Ta. This can be said because a working electrode on the surface of substrate 300 is a hybrid electrode of the Cu film 260 and the barrier metal film 240 of Ta. Thus it is possible to obtain similar effects to the embodiment 1.

Embodiments have been explained above while referring to some practical examples. But, this invention should not be limited to these practical examples only. Although in the embodiments the low-k film 220 was used as a dielectric film, this is not the one that limits the invention, and no problems occur even in cases where other dielectric materials are used. For example, a silicon oxide film (SiO₂) is employable.

Additionally, regarding the film thickness of the interlayer dielectric film along with the size, shape and number of the holes, the ones that are needed in semiconductor integrated circuits and/or various types of semiconductor circuit elements may be adequately chosen and used on a case-by-case basis.

Any other semiconductor device fabrication methods and polishing methods and polishing apparatuses which comprise the elements of this invention and which are design-alterable ad libitum by those skilled in the art should be interpreted to fall within the scope of this invention.

Additionally, although explanations as to those techniques and schemes which are usually employed in the semiconductor industry—for example, photolithography processes, pre- and post-cleaning processes and like processes—are omitted for brevity of the description, it is needless to say that such processes are includable in the coverage of the invention.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method for fabricating a semiconductor device, comprising:
forming a barrier metal film on a substrate with an opening defined therein;
forming a copper-containing film on said barrier metal film after having formed said barrier metal film on a surface of said substrate and an inner wall of said opening; and
polishing said copper-containing film and said barrier metal film while applying a voltage to said substrate in a state that said copper-containing film and said barrier metal film are exposed.

2. The method according to claim 1, wherein said voltage is applied in a way such that a potential of a hybrid system of said copper-containing film and said barrier metal film becomes 0.6 to 1.0 volt versus Ag/AgCl.

3. The method according to claim 1, wherein either one of tantalum (Ta)-containing material and titanium (Ti)-containing material is used as a material of said barrier metal film.

4. The method according to claim 1, further comprising:
prior to applying the voltage to said substrate, polishing said copper-containing film as formed on said barrier metal film until said barrier metal film is exposed.

5. The method according to claim 4, further comprising:
after having polished said copper-containing film until said barrier metal film is exposed, measuring a potential of a hybrid system of said copper-containing film and said barrier metal film.

6. The method according to claim 5, wherein based on a result of the measurement of the potential of said hybrid system, said voltage is applied to the substrate to thereby control the potential of said hybrid system.

7. The method according to claim 6, wherein said copper-containing film and said barrier metal film thus exposed are polished together in a state that the potential of said hybrid system is controlled.

8. The method according to claim 1, wherein said voltage is applied from a side face of said substrate.

9. The method according to claim 1, wherein said voltage is applied from a back surface of said substrate.

10. The method according to claim 1, wherein a polishing pad having electrical conductivity is used to apply the voltage to said substrate through said polishing pad.

11. The method according to claim 1, wherein a slurry is used for said polishing, and wherein said method further comprises:
measuring in advance a natural potential of a material piece of said barrier metal film in said slurry; and
based on the measured natural potential of said material piece, setting said voltage to be applied when polishing said copper-containing film and said barrier metal film exposed.

12. The method according to claim 11, further comprising:
in case said natural potential is less than 0.6 V vs. Ag/AgCl, operating an application voltage in such a way that said natural potential becomes 0.6 to 1.0 V vs. Ag/AgCl; and
applying a voltage similar to said application voltage being operated when polishing said copper-containing film and said barrier metal film thus exposed.

13. A method for fabricating a semiconductor device comprising:
measuring a potential of a hybrid system of a copper-containing film and a barrier metal film when a slurry is supplied to a substrate with said copper-containing film and said barrier metal film being exposed at a surface of said substrate; and
based on a result of said measuring, using said slurry to polish said copper-containing film and said barrier metal film while applying a voltage to said substrate.

14. The method according to claim 13, wherein said voltage is applied so that a potential of said hybrid system becomes 0.6 to 1.0 V vs. Ag/AgCl.

15. The method according to claim 13, wherein any one of tantalum (Ta)-containing material and titanium (Ti)-containing material is used as a material of said barrier metal film.

16. A polishing apparatus comprising:
a polishing unit operative to polish a substrate surface by use of a chemical liquid; and
a potential measurement unit configured to measure a potential of said substrate surface with said chemical liquid being as an electrolytic material.

17. The apparatus according to claim 16, wherein said potential measurement unit has a working electrode, a reference electrode and an counter electrode.

18. The apparatus according to claim 17, wherein said potential is measured by causing said working electrode to be in contact with said substrate.

19. The apparatus according to claim 18, wherein said potential is measured by letting said reference electrode and said counter electrode be put in said chemical liquid.

20. The apparatus according to claim 19, further comprising:
a reservoir which stores therein said chemical liquid as used for the polishing and which permits said reference electrode and said counter electrode to be put together in said chemical liquid being stored.
